(19) United States
(12) Patent Application Publication
(10) Pub. No.: US 2005/0089177 A1
(43) Pub. Date: Apr. 28, 2005

(54) Method, apparatus, and program for intelligent volume control

(75) Inventors: Nathan Raymond Hughes, Round Rock, TX (US); Nishant Srinath Rao, San Antonio, TX (US); Michelle Ann Uretsky, Austin, TX (US)

Correspondence Address: IBM CORP (YA);C/O YEE & ASSOCIATES PC, P.O. BOX 802333, DALLAS, TX, 75380, US

(73) Assignee: International Business Machines Corporation, Armonk, NY (US)

(21) Appl. No.: 10/692,168

(22) Filed: Oct. 23, 2003

(51) Int. Cl. H04B 1/00; H03G 3/00

(52) U.S. Cl. 381/86; 381/104

(57) ABSTRACT

An intelligent volume control is provided for an audio system that adjusts a volume level based on several input parameters. The input parameters may vary depending upon the environment of the audio system. The listener may manually set a volume to a desired level relative to environmental noise and interference. The volume level and input parameters are stored as a data point. As values for the input parameters change, the volume control performs statistical analysis on the stored data point to predict a desired volume level. The audio system then adjusts the volume to the predicted level. The listener may then override the volume level and set another data point. Thus, the volume control learns from the volume levels set by the listener and the values of the input parameters.

### BACKGROUND OF THE INVENTION

1. Technical Field

The present invention relates to data processing and, in particular, to audio playback control. Still more particularly, the present invention provides a method, apparatus, and program for intelligent volume control in an audio system.

2. Description of Related Art

Audio systems are used in a variety of environments, such as within homes, in automobiles, on boats, etc. In most environments, the interior and/or exterior conditions may result in audio interference. For example, in a home with several family members, children may cry, dogs may bark, the phone may ring, or someone may run a vacuum cleaner. In these cases, a person listening to an audio system may have to repeatedly adjust the volume up and down to remain at a desired level relative to environmental noise and interference. As another example, in an automobile the environmental noise level may increase due to road noise when it is raining or engine nose when driving at a greater speed.

Volume control systems exist which adjust the volume level according to the speed of an automobile. However, these systems have one input parameter and only one fixed output for each value of the one input parameter. The factory settings for such a volume control system may not be sufficient or desirable for every user. Thus, the listener may still need to adjust the volume up and down to a desirable level based upon actual conditions.

### SUMMARY OF THE INVENTION

The present invention provides intelligent volume control for an audio system that adjusts a volume level based on several input parameters. The input parameters may vary depending upon the environment of the audio system. The listener may manually set a volume to a desired level relative to environmental noise and interference. The volume level and input parameters are stored as a data point. As values for the input parameters change, the volume control performs statistical analysis on the stored data point to predict a desired volume level. The audio system then adjusts the volume to the predicted level. The listener may then override the volume level and set another data point. Thus, the volume control of the present invention learns from the volume levels set by the listener and the values of the input parameters.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a block diagram of a data processing system in which the present invention may be implemented;

FIG. 2 is a block diagram of an audio system in accordance with a preferred embodiment of the present invention;

FIG. 3 is a block diagram illustrating a volume prediction mechanism in accordance with a preferred embodiment of the present invention;

FIGS. 4A-4D depict example data points for volume levels in accordance with a preferred embodiment of the present invention;

FIG. 5 is a flowchart illustrating the operation of storing a data point responsive to a user manually setting the volume level in accordance with a preferred embodiment of the present invention;

FIG. 6 is a flowchart illustrating the operation of an intelligent volume control mechanism in accordance with a preferred embodiment of the present invention;

FIG. 7 is a flowchart illustrating the operation of a volume level prediction module in accordance with a preferred embodiment of the present invention.

### DETAILED DESCRIPTION OF THE PREFERRED EMBODIMENT

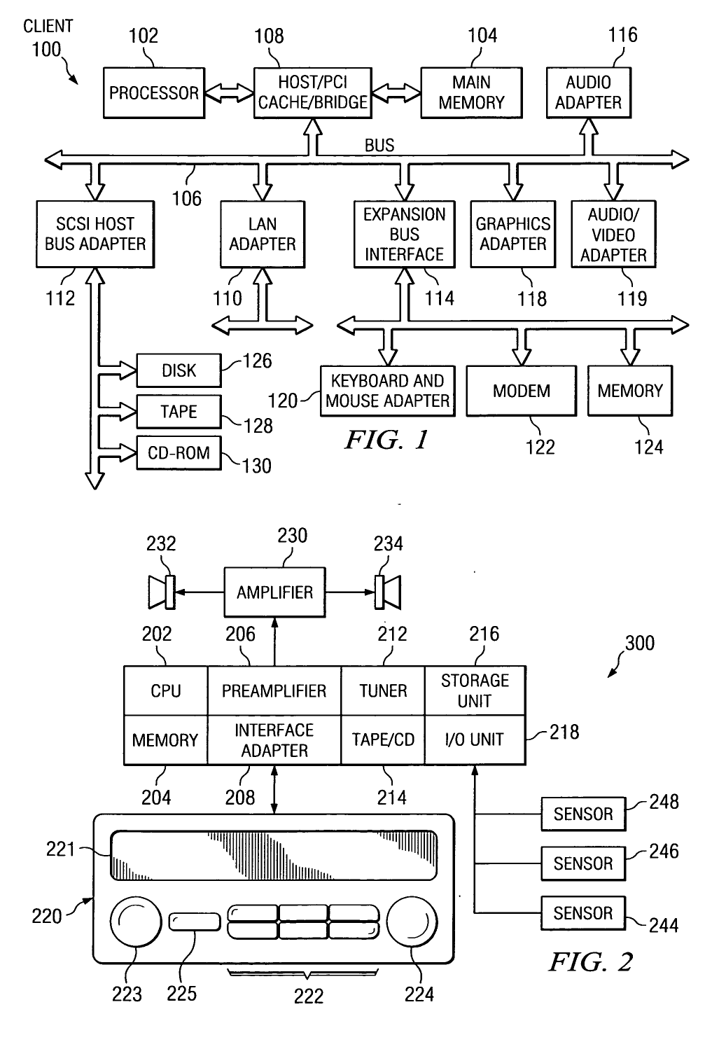

With reference now to the figures and in particular with reference to FIG. 1, a block diagram of a data processing system is shown in which the present invention may be implemented. Data processing system 100 is an example of a computer in which code or instructions implementing the processes of the present invention may be located. Data processing system 100 may be employed as an audio system for playing audio media. For example, the data processing system may be used to play compact disks or MP3 audio files.

Data processing system 100 employs a peripheral component interconnect (PCI) local bus architecture. Although the depicted example employs a PCI bus, other bus architectures such as Accelerated Graphics Port (AGP) and Industry Standard Architecture (ISA) may be used. Processor 102 and main memory 104 are connected to PCI local bus 106 through PCI bridge 108. PCI bridge 108 also may include an integrated memory controller and cache memory for processor 102. Additional connections to PCI local bus 106 may be made through direct component interconnection or through add-in boards.

In the depicted example, local area network (LAN) adapter 110, small computer system interface SCSI host bus adapter 112, and expansion bus interface 114 are connected to PCI local bus 106 by direct component connection. In contrast, audio adapter 116, graphics adapter 118, and audio/video adapter 119 are connected to PCI local bus 106 by add-in boards inserted into expansion slots. Expansion bus interface 114 provides a connection for a keyboard and mouse adapter 120, modem 122, and additional memory 124. SCSI host bus adapter 112 provides a connection for hard disk drive 126, tape drive 128, and CD-ROM drive 130. Typical PCI local bus implementations will support three or four PCI expansion slots or add-in connectors.

An operating system runs on processor 102 and is used to coordinate and provide control of various components within data processing system 100 in FIG. 1. The operating system may be a commercially available operating system such as Windows XP, which is available from Microsoft Corporation. An object oriented programming system such as Java may run in conjunction with the operating system and provides calls to the operating system from Java programs or applications executing on data processing system 100. “Java” is a trademark of Sun Microsystems, Inc. Instructions for the operating system, the object-oriented programming system, and applications or programs are located on storage devices, such as hard disk drive 126, and may be loaded into main memory 104 for execution by processor 102.

Audio may be played through audio adapter 116. The user may control the playback through a user interface via graphics adapter 118 and keyboard and mouse adapter 120. In accordance with a preferred embodiment of the present invention, data processing system 100 includes an intelligent volume control that adjusts a volume level based on input parameters. The input parameters may vary depending upon the environment of the audio system. For example, if the data processing system is located in a user's bedroom, the data processing system may receive input from a sensor that measures a noise level. Therefore, if environmental noise increases due to people outside the room talking or a person using a vacuum cleaner, the volume control will adjust the volume accordingly.

The listener may manually set a volume to a desired level relative to environmental noise and interference. The volume level and input parameters are stored as a data point. As values for the input parameters change, the volume control performs statistical analysis on the stored data point to predict a desired volume level. The audio system then adjusts the volume to the predicted level. The listener may then override the volume level and set another data point. Thus, the volume control of the present invention learns from the volume levels set by the listener and the values of the input parameters.

Those of ordinary skill in the art will appreciate that the hardware in FIG. 1 may vary depending on the implementation. Other internal hardware or peripheral devices, such as flash read-only memory (ROM), equivalent nonvolatile memory, or optical disk drives and the like, may be used in addition to or in place of the hardware depicted in FIG. 1. Also, the processes of the present invention may be applied to a multiprocessor data processing system.

For example, data processing system 100, if optionally configured as a network computer, may not include SCSI host bus adapter 112, hard disk drive 126, tape drive 128, and CD-ROM 130. In that case, the computer, to be properly called a client computer, includes some type of network communication interface, such as LAN adapter 110, modem 122, or the like. As another example, data processing system 100 may be a stand-alone system configured to be bootable without relying on some type of network communication interface, whether or not data processing system 100 comprises some type of network communication interface. As a further example, data processing system 100 may be a personal digital assistant (PDA), which is configured with ROM and/or flash ROM to provide non-volatile memory for storing operating system files and/or user-generated data.

The depicted example in FIG. 1 and above-described examples are not meant to imply architectural limitations. For example, data processing system 100 also may be a notebook computer or hand held computer in addition to taking the form of a PDA. Data processing system 100 also may be a kiosk or a Web appliance.

The processes of the present invention are performed by processor 102 using computer implemented instructions, which may be located in a memory such as, for example, main memory 104, memory 124, or in one or more peripheral devices 126-130.

With reference now to FIG. 2, a block diagram of an audio system is depicted in accordance with a preferred embodiment of the present invention. Audio system 200 may be located in a vehicle, such as an automobile, truck, or boat. Audio system 200 includes central processing unit (CPU) 202, which may be an embedded processor or processor, such as a Pentium processor from Intel Corporation. “Pentium” is a trademark of Intel Corporation. Audio system 200 also includes memory 204, which may take the form of random access memory (RAM) and/or read only memory (ROM).

Audio system 200 includes preamplifier 206, which provides audio output to amplifier 230. Audio is presented to the listener via speakers 232, 234. Although two speakers are shown in FIG. 2, more or fewer speakers may be included depending upon the implementation. In many automobile stereo systems, four, five, six, or even seven speakers are typically used.

Interface adapter 208 receives input from and presents display output to interface 220. Audio system 200 receives audio input from, for example, AM/FM tuner 212 and tape and/or CD player 214. Other audio input may also be used, such as, for example, streaming Internet radio, digital video disk (DVD) audio, or satellite radio. Audio system 200, under control of CPU 202, operates the functions of the tuner, the tape player, and/or the CD player according to user interaction with the interface.

Interface 220 includes display 221, buttons 222, volume control knob 223, and tuner knob 224. Volume level may be adjusted in preamplifier 206. by manipulating volume control knob 223. Manipulation of tuner knob 224 results in tuner 212 changing radio stations. More or fewer buttons and/or knobs may be included within interface 220 depending upon the implementation. For example, volume and/or tuner control may be performed digitally through buttons, sliders, or a touch screen. Audio system 200 may alternatively include voice control functionality or steering wheel mounted controls.

Audio system 200 also includes a storage device unit 216. The storage unit may contain one or more storage devices, such as, for example, a hard disk drive, a flash memory, a DVD drive, or a floppy disk. Audio system 200 also includes an input/output (I/O) unit 218, which provides connections to various I/O devices. Several sensors 244, 246, 248 are connected to I/O unit 218. These sensors may include sensors that detect speed, whether a window is open or closed, interior or exterior noise levels, whether a convertible top is up or down, windshield wiper use and/or level, whether the headlights are on, global positioning system (GPS) coordinates, etc. In other words, almost any condition or parameter in, about, or around an automobile may be detected through the use of sensors 244, 246, 248.

In accordance with a preferred embodiment of the present invention, audio system 200 includes an intelligent volume control function that adjusts a volume level based on input parameters. The input parameters may be received from sensors 244, 246, 248. The listener may manually set a volume to a desired level relative to environmental noise and interference. “Learn” button 225 may be provided on interface 220. This button may be selected by the listener when the listener wishes to have the audio system learn the volume level with respect to the input parameters.

The volume level and input parameters are stored as a data point. CPU 202 may sample the values of sensors 244-248 via I/O unit 218 periodically, such as, for example, every second. As values for the input parameters change, the volume control performs statistical analysis on the stored data point to predict a desired volume level. The audio system then adjusts the volume to the predicted level. The listener may then override the volume level and set another data point by selecting button 225. Thus, the volume control of the present invention learns from the volume levels set by the listener and the values of the input parameters.

The intelligent volume control mechanism of the present invention may also be used to adjust other audio output parameters, such as balance, fade, bass, treble, or equalizer settings. For example, if a window is open on the passenger's side of an automobile, the balance may be adjusted to increase the volume on that side. If the windows are open in the back of an automobile, the fade may be adjusted to increase the volume in the rear speakers.

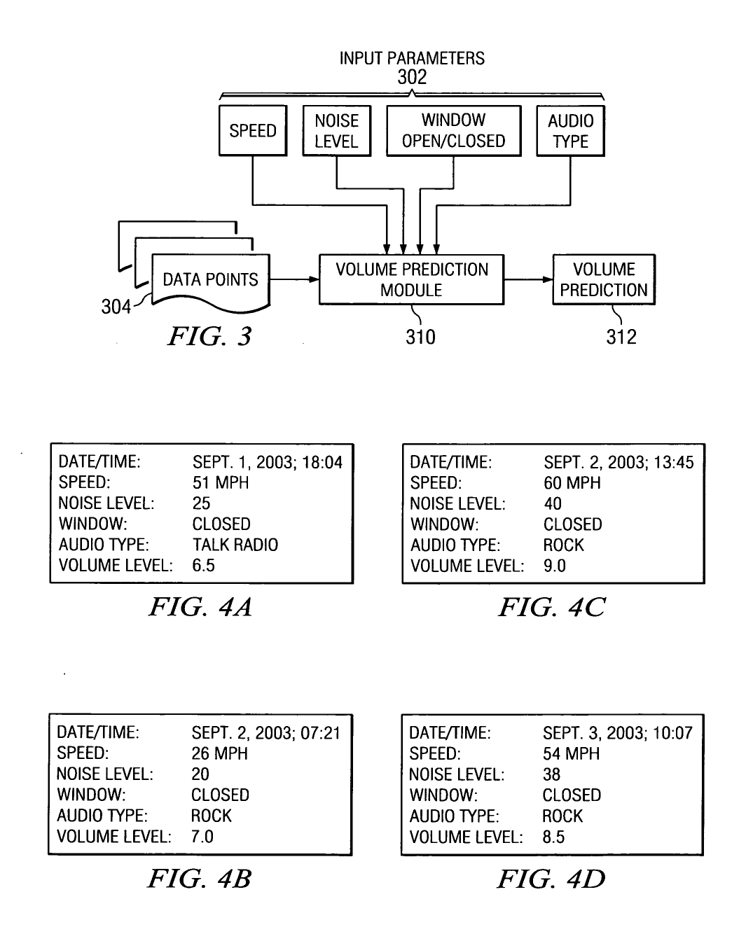

FIG. 3 is a block diagram illustrating a volume prediction mechanism in accordance with a preferred embodiment of the present invention. Volume prediction module 310 receives input parameters 302. In the depicted example, the input parameters include speed, noise level, window open/closed, and audio type. Audio type may be received from an audio medium, such as a compact disk, MP3 file, or radio station. For example, a listener may be listening to rock music on a CD, a talk radio station, or a comedy show on MP3.

When a value of one of input parameters 302 changes, volume prediction module 310 receives data points 304 from storage. Data points 304 are historical data points consisting of a volume level associated with a set of input parameter values. The data points may be time stamped and stored in a persistent storage, such as, for example, a database. Data points 304 may be selected based on input parameters 302. For example, if the windows are open, prediction module 310 may rule out any data points for which the windows were closed. The prediction module may also consider only data points for which a parameter is within an acceptable proximity to the corresponding input parameter. For example, if the speed input parameter is 55 miles per hour (MPH), then the prediction module may consider only data points for which the speed is 50-60 MPH.

The volume prediction module then performs statistical analysis to determine volume prediction 312. For example, if ten data points exist with the exact same input parameter values, the volume prediction module may take an average of the five most recently set volume levels. The volume prediction module may also remove outliers, perform curve fitting, perform linear extrapolation, perform linear regression analysis, perform multiple regression analysis, and perform other data mining and statistical analysis techniques commonly known in the industry.

Outliers are data points that deviate from expected values or the statistical trend of the other data points. Outliers may skew results of statistical analysis and are preferably removed.

Regression is a functional relationship between two or more correlated variables that is often empirically determined from data and is used especially to predict values of one variable when given values of the others. Linear regression (or any other regression) seeks to find the equation of the line (or curve) that best fits the data set. Therefore, curve fitting may employ linear regression (for a line, which is a special case of a curve) or non-linear regression (for a curve) to determine a “best fit” curve given the data points. From this “best fit,” the data points may be extrapolated to find values, given variables for which a data point does not exist.

Multiple regression is a statistical technique which allows one to examine the relationship between two or more predictor variables (PVs) and a criterion variable (CV). Simple linear regression is limited to a single predictor variable. Predictor variables (a.k.a. independent variables) are variables one manipulates or has some control over. Criterion variables (a.k.a. dependent variables) are variables one measures during an experiment. Specifically, when the criterion variable is studied as a function of the predictor variables, multiple regression analysis may be employed. Multiple regression allows one to determine a linear relationship between variables that can be used in prediction.

Volume prediction 312 may be stored as a data point, which identifies the predicted volume level with respect to a given set of parameters. For example, volume prediction 312 may be a number between 0 and 10, where 10 is the loudest, although the numerical range convention may vary depending upon the implementation. The volume prediction module 310 may continuously fill in data points even when the audio system is not producing audio output. In other words, whenever sensor data is sampled, the volume prediction module may generate a prediction, which may be stored as a data point as if the user deliberately set the value. These data points may be identified as predictions using, for example, a flag or Boolean variable to distinguish these points from data points actually set by the user. Prediction data points may be overridden with manually selected volume level data points and may be recalculated as input variables change. The volume may then be adjusted in real time by retrieving a data point that is closest to the input parameters. Alternatively, volume prediction 312 may be used to adjust the volume of the audio system on the fly.

Audio type may simply include categories of audio, such as 80's, 90's, rock, classical, jazz, talk, etc. Alternatively, audio type may identify a particular CD, song, show, or commercial. A listener may listen to an entire CD and increase the volume only for a particular song on the CD. A data point may be saved for each song and, thus, volume prediction module 310 may predict a new volume level responsive to a change in song, even if the CD or radio station does not change. Furthermore, the volume prediction will be based on input parameters 302; therefore, the volume will be adjusted to take into account the environmental noise or interference.

A song may be identified in a table of contents on a CD or through a look-up mechanism. CD look-up mechanisms, such as CDDB, Gracenote, and FreeDB, are commonly known in the computer media player industry. Also, digital radio, such as satellite radio or Internet radio, may include identification and category information. MP3 files typically include song, artist, and category information in an embedded tag file. Therefore, this information may be provided by the media source itself, rather than a sensor.

In an alternative embodiment, data points may be stored for a plurality of users. Users may be identified, for example, when a particular driver uses a keychain remote to unlock or start the car. Many automobiles use an identifier in the keychain remote to identify the driver. The listener may also be identified by selecting a seat position preset button, by voice identification, or other identification techniques known in the art. The volume prediction module may then predict preferred volume levels on a user-by-user basis.

FIGS. 4A-4D depict example data points for volume levels in accordance with a preferred embodiment of the present invention. As shown in FIG. 4A, a data point may include a date/time, speed, noise level, window status, audio type, and volume level. In the example shown in FIG. 4A, the automobile was traveling 51 MPH, the external noise level had a value of 25, the windows were closed, the user was listening to talk radio, and the volume was set at 6.5. Noise levels and volume levels may be in any scale. Typically volume levels are on a scale of zero to ten; however, any convention may be used.

As another example, FIG. 4B shows a data point for which the automobile was traveling 26 MPH, the external noise level had a value of 20, the windows were closed, the user was listening to rock music, and the volume was set at 7.0. Clearly, the listener prefers to listen to rock music at a higher volume level, especially considering the lower speed and lower external noise level.

As shown in FIG. 4C, the speed increased to 60 MPH and the noise level increased to a value of 40. The listener was still listening to rock music with the windows closed. However, the listener increased the volume to 9.0. Based upon these data points, it is clear that the listener prefers to significantly increase the volume at higher speeds and resulting higher external noise levels. As shown in FIG. 4D, the speed decreased to 54 MPH and the noise level decreased to a value of 38. The volume is decreased to 8.5.

Suppose input parameters are received such that the speed then increases to 55 MPH. Given these data points, the intelligent volume control mechanism of the present invention may perform an average of the closest data points, shown in FIGS. 4C and 4D, to predict a volume level of 8.75. Alternatively, the intelligent volume control mechanism may perform curve fitting to predict a volume level of 8.6.

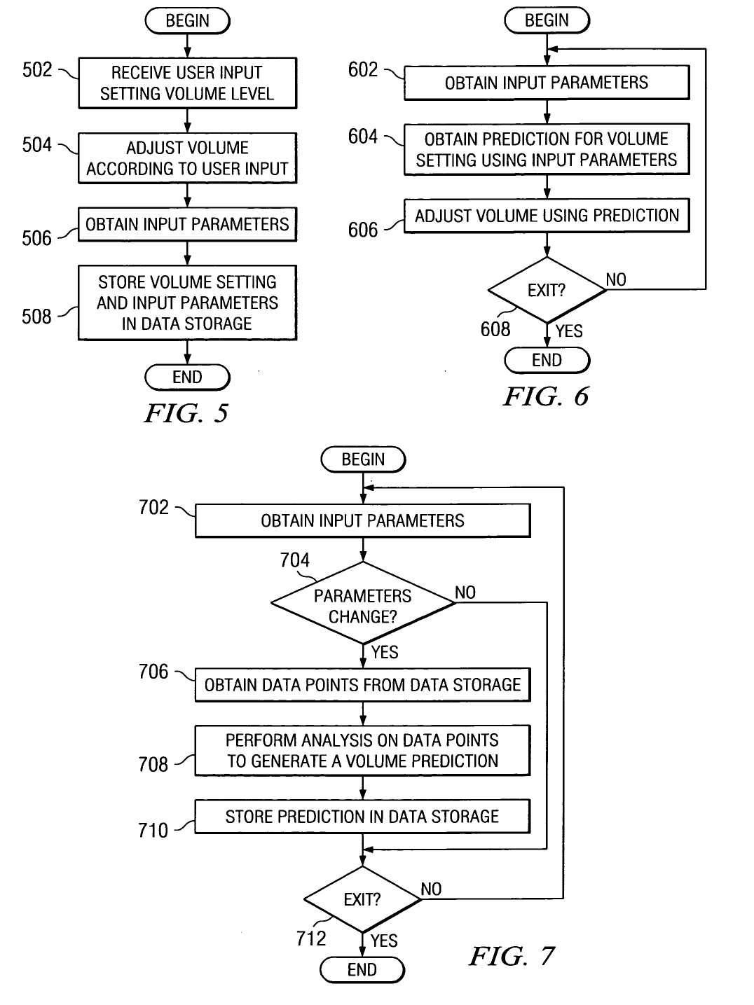

With reference now to FIG. 5, a flowchart is shown illustrating the operation of storing a data point responsive to a user manually setting the volume level in accordance with a preferred embodiment of the present invention. The process begins and receives user input setting the volume level (step 502) and adjusts the volume according to the user input (step 504). Then, the process obtains input parameters (step 506) and stores the volume setting and input parameters as a data point in data storage (step 508). Thereafter, the process ends.

Turning now to FIG. 6, a flowchart illustrating the operation of an intelligent volume control mechanism is shown in accordance with a preferred embodiment of the present invention. The process begins and obtains input parameters (step 602). The process then obtains a prediction for the volume setting using the input parameters (step 604). The process may obtain a prediction by retrieving a closest data point based on the input parameters or, alternatively, may perform statistical analysis on data points on the fly to determine a volume prediction.

The process adjusts the volume using the volume prediction (step 606). Next, a determination is made as to whether an exit condition exists (step 608). An exit condition may exist, for example, when the audio system is turned off or when a user turns off the intelligent volume control mechanism. If an exit condition exists, the process ends. Otherwise, the process returns to step 602 to obtain input parameters.

Next, with reference to FIG. 7, a flowchart is shown illustrating the operation of a volume level prediction module in accordance with a preferred embodiment of the present invention. The process begins and obtains input parameters (step 702). A determination is made as to whether one or more input parameters have changed (step 704). If input parameters have changed, the process obtains data points from data storage (step 706) and performs analysis on the data points to generate a volume prediction (step 708).

Next, the process stores the prediction in data storage as a data point (step 710) and a determination is made as to whether an exit condition exists (step 712). An exit condition may exist, for example, when the volume level prediction module is turned off. If an exit condition exists, the process ends. Otherwise, the process returns to step 702 to obtain input parameters. Returning to step 704, if input parameters have not changed, the process continues to step 712 to determine whether an exit condition exists.

Thus, the present invention solves the disadvantages of the prior art by providing an intelligent volume control for an audio system that adjusts a volume level based on several input parameters. The input parameters may vary depending upon the environment of the audio system. As values for the input parameters change, the volume control performs statistical analysis on data points to predict a desired volume level. The audio system then adjusts the volume to the predicted level.

Thus, the volume control of the present invention learns from the volume levels set by the listener and the values of the input parameters. As the volume control learns the preferred volume levels of the listener, the listener needs to adjust the volume manually on fewer and fewer occasions. The listener may then use the audio system in a vehicle, for example, and concentrate on driving, rather than on repeatedly adjusting the volume to counteract environmental noise.

It is important to note that while the present invention has been described in the context of a fully functioning data processing system, those of ordinary skill in the art will appreciate that the processes of the present invention are capable of being distributed in the form of a computer readable medium of instructions and a variety of forms and that the present invention applies equally regardless of the particular type of signal bearing media actually used to carry out the distribution. Examples of computer readable media include recordable-type media such a floppy disc, a hard disk drive, a RAM, and CD-ROMs and transmission-type media such as digital and analog communications links.

The description of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

1. A method for intelligent audio output control, the method comprising:
obtaining values for a set of input parameters;
obtaining an audio output parameter prediction based on the values for the set of input parameters; and
adjusting an audio output parameter for an audio system using the audio output parameter prediction.

2. The method of claim 1, wherein the step of obtaining values for a set of input parameters includes receiving values from one or more sensors.

3. The method of claim 1, wherein the set of input parameters includes at least one of speed, whether a window is open or closed, interior or exterior noise levels, whether a convertible top is up or down, windshield wiper use, windshield wiper level, whether headlights are on, and global positioning system (GPS) coordinates.

4. The method of claim 1, wherein the set of input parameters includes audio type.

5. The method of claim 1, wherein the step of obtaining an audio output parameter prediction includes:
receiving a plurality of data points, wherein each data point includes a value for each of the set of input parameters and an audio output parameter value; and
performing statistical analysis on the plurality of data points to determine an audio output parameter prediction.

6. The method of claim 5, wherein the statistical analysis includes at least one of performing an average, performing linear regression analysis, performing multiple regression analysis, performing linear extrapolation, performing curve fitting, and removing outliers.

7. The method of claim 5, further comprising:
storing the values for the set of input parameters and the audio output parameter prediction as a data point.

8. The method of claim 1, further comprising:
receiving user input of an audio output parameter value;
obtaining values for the set of input parameters; and
storing the values for the set of input parameters and the audio output parameter value as a data point.

9. The method of claim 1, wherein the step of obtaining an audio output parameter prediction includes:
identifying a closest data point within a plurality of historical data points; and
setting the audio output parameter prediction to an audio output parameter value of the closest data point.

10. The method of claim 1, wherein the audio output parameter is one of volume level, balance, fade, bass, treble, and equalizer settings.

11. An apparatus for intelligent audio output control, the apparatus comprising:
means for obtaining values for a set of input parameters;
means for obtaining an audio output parameter prediction based on the values for the set of input parameters; and
means for adjusting an audio output parameter for an audio system using the audio output parameter prediction.

12. The apparatus of claim 11, wherein the means for obtaining values for a set of input parameters includes one or more sensors.

13. The apparatus of claim 11, wherein the set of input parameters includes at least one of speed, whether a window is open or closed, interior or exterior noise levels, whether a convertible top is up or down, windshield wiper use, windshield wiper level, whether headlights are on, and global positioning system (GPS) coordinates.

14. The apparatus of claim 11, wherein the set of input parameters includes audio type.

15. The apparatus of claim 11, wherein the means for obtaining an audio output parameter prediction includes:
means for receiving a plurality of data points, wherein each data point includes a value for each of the set of input parameters and an audio output parameter value; and
means for performing statistical analysis on the plurality of data points to determine an audio output parameter prediction.

16. The apparatus of claim 15, wherein the statistical analysis includes at least one of performing an average, performing linear regression analysis, performing multiple regression analysis, performing linear extrapolation, performing curve fitting, and removing outliers.

17. The apparatus of claim 15, further comprising:
means for storing the values for the set of input parameters and the audio output parameter prediction as a data point.

18. The apparatus of claim 11, further comprising:
means for receiving user input of an audio output parameter value;
means for obtaining values for the set of input parameters; and
means for storing the values for the set of input parameters and the audio output parameter value as a data point.

19. The apparatus of claim 11, wherein the means for obtaining an audio output parameter prediction includes:
means for identifying a closest data point within a plurality of historical data points; and
means for setting the audio output parameter prediction to an audio output parameter value of the closest data point.

20. The apparatus of claim 11, wherein the audio output parameter is one of volume level, balance, fade, bass, treble, and equalizer settings.

21. A computer program product, in a computer readable medium, for intelligent audio output control, the computer program product comprising:
instructions for obtaining values for a set of input parameters;
instructions for obtaining an audio output parameter prediction based on the values for the set of input parameters; and
instructions for adjusting an audio output parameter for an audio system using the audio output parameter prediction.
